(19) United States
(12) Patent Application Publication
(10) Pub. No.: US 2007/0164349 A1
(43) Pub. Date: Jul. 19, 2007

(54) CIRCUIT BOARD, CIRCUIT APPARATUS, AND METHOD OF MANUFACTURING THE CIRCUIT BOARD

(75) Inventors: Mayumi Nakasato, Ogaki-city (JP); Makoto Murai, Isehara-City (JP); Ryosuke Usui, Ichinomiya-City (JP); Hideki Mizuhara, Ichinomiya-City (JP); Yasunori Inoue, Ogaki-City (JP)

Correspondence Address: DITTHAVONG MORI & STEINER, P.C., 918 Prince St., Alexandria, VA, 22314, US

(73) Assignee: Sanyo Electric Co., Ltd., Anpachi-gun (JP)

(21) Appl. No.: 11/616,182

(22) Filed: Dec. 26, 2006

(30) Foreign Application Priority Data
Dec. 27, 2005 (JP) 2005-374033

(51) Int. Cl. H01L 29/788

(52) U.S. Cl. 257/318

(57) ABSTRACT

A circuit board includes a substrate and an insulating layer. The substrate has a first surface. The insulating layer has a second surface and is connected to the substrate. The first surface is in contact with the second surface. Heat-conductive particles are provided in the insulating layer. A part of the particles projects from the second surface of the insulating layer and is in contact with the first surface of the substrate.

### CROSS-REFERENCE TO RELATED APPLICATIONS

The present application claims priority under 35 U.S.C. §119 to Japanese Patent Application No. 2005-374033, filed Dec. 27, 2005, entitled “CIRCUIT BOARD, CIRCUIT APPARATUS USING CIRCUIT BOARD, AND METHOD OF MANUFACTURING CIRCUIT BOARD.” The contents of this application are incorporated herein by reference in their entirety.

### BACKGROUND OF THE INVENTION

1. Field of the Invention

The present invention relates to a circuit board, a circuit apparatus and a method of manufacturing a circuit board.

2. Discussion of the Background

In recent years, circuit apparatuses incorporated in electronic equipment and the like have required greater miniaturization, higher densities, and increased functionality. The circuit apparatuses have thus grown in heat generation density per unit volume. For this reason, metal substrates and the like having high radiation performance are used as circuit boards of the circuit apparatuses, and IC (Integrated Circuit) and LSI (Large Scale Integrated circuit) and the like are mounted on the metal substrates. The use of metal substrates as circuit boards is disclosed, for example, in Japanese Patent Laid-Open Publication No. Hei 8-288605. The structure composed of Hybrid IC (Hybrid Integrated Circuit) on the metal substrates is also conventional. Here, Hybrid IC denotes a circuit apparatus including IC chips, capacitors, and resistors integrated all together on a circuit board.

FIG. 7 is a sectional view schematically showing the structure of a conventional circuit apparatus disclosed in Japanese Patent Laid-Open Publication No. Hei 8-288605. With reference to FIG. 7, a resin layer 102 with a filler composed of silica (SiO2) added is formed on a metal substrate 101 composed of Aluminum in the conventional circuit apparatus. An IC chip 104 is mounted on a predetermined area of the resin layer 102 via an adhesion layer 103 composed of resin. Also, a wiring pattern layer 105 composed of copper (Cu) is formed on a surface of the resin layer 102 with a predetermined distance from the sides of the IC chip 104 via the adhesion layer 103. The wiring pattern layer 105 and the metal substrate 101 are insulated electrically by the resin layer 102.

The conventional circuit apparatus shown in FIG. 7 uses the metal substrate 101 of Aluminum. By mounting the IC chip 104 on the metal substrate 101 via the resin layer 102, great amount of heat released from the IC chip 104 can be radiated through the metal substrate 101.

In general, coefficient of thermal conductivity has been improved by filling particulate fillers of silica and the like in insulating layer. In the conventional circuit apparatus shown in FIG. 7, while an increase in the volumetric filling rate of the fillers (typically 70 to 80 vol %) leads to a sharp rise in the coefficient of thermal conductivity, however heat generated from IC chip 104 leads to an increase in the temperature of the whole circuit apparatus. This results in an expansion of the resin layer 102 which has large coefficient of thermal conductivity. Therefore, the structure of the resin layer 102 (insulating layer) mounted on the metal substrate 101 in the conventional circuit apparatus causes a problem of thermal strain which brings deformation in the circuit apparatus. Also, depending upon conditions, the thermal strain could result in a problem of exfoliation between the metal substrate 101 and the resin layer 102 (insulating layer).

### SUMMARY OF THE INVENTION

According to one aspect of the present invention, a circuit board includes a substrate and an insulating layer. The substrate has a first surface. The insulating layer has a second surface and is connected to the substrate. The first surface is in contact with the second surface. Heat-conductive particles are provided in the insulating layer. A part of the particles projects from the second surface of the insulating layer and is in contact with the first surface of the substrate.

According to another aspect of the present invention, a circuit board includes a substrate and an insulating layer. The substrate has a first surface. The insulating layer has a second surface and is connected to the substrate. The first surface is in contact with the second surface. Heat-conductive particles are provided in the insulating layer. A part of the particles projects from the second surface of the insulating layer and is in contact with the first surface of the substrate. A circuit element is provided on the insulating layer.

According to further aspect of the present invention, a method of manufacturing a circuit board includes providing a substrate and press-bonding an insulating layer including heat-conductive particles to the substrate in a press-bonding direction.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a sectional view showing the configuration of a circuit board according to a first embodiment of the present invention;

FIGS. 2A to 2F are sectional views showing the steps of a method of manufacturing the circuit board according to the first embodiment of the present invention;

FIG. 3 is a sectional view showing the configuration of a circuit apparatus according to a second embodiment of the present invention;

FIGS. 4A to 4K are sectional views for explaining the process for manufacturing the circuit apparatus according to the second embodiment of the present invention;

FIG. 5 is a sectional view showing a circuit apparatus according to a third embodiment of the present invention;

FIGS. 6A to 6K are sectional views for explaining the process for manufacturing the circuit apparatus according to the third embodiment of the present invention; and

FIG. 7 is a sectional view schematically showing the configuration of a conventional circuit apparatus.

### DESCRIPTION OF THE EMBODIMENTS

The embodiments will now be described with reference to the accompanying drawings, wherein like reference numerals designate corresponding or identical elements throughout the various drawings.

As employed in this specification, the “top” direction is defined by the sequential order of mounting layers, i.e., the direction of latterly-mounted layer from formerly-mounted layer.

### First Embodiment

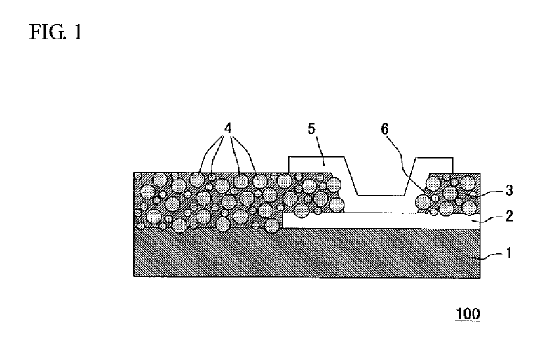

FIG. 1 is a sectional view showing the configuration of a circuit board according to a first embodiment of the present invention. The circuit board 100 includes a substrate 1, a first wiring layer 2, an insulating layer 3, a filler (particulates) 4, a second wiring layer 5, and a via hole 6.

The substrate 1 is composed of a material with glass cloth (glass fiber) impregnated with insulating resin. Suitable insulating resins include organic resins such as epoxy resins, melamine derivatives such as BT resin, liquid crystal polymer, PPE resins, polyimide resins, fluorine resins, phenol resins, and polyamide bismaleimides. The substrate 1 has a thickness of, for instance, about 60 μm. Preferably, three layers of the glass cloth are disposed within the epoxy resin. In this instance, one single layer refers to a configuration where glass fibers extending in respective different directions cross each other. The three layers thus refer to the state where this unit configuration is stacked up to three stages in the vertical direction.

The first wiring layer 2 and the second wiring layer 5 disposed on the substrate 1 constitute a part of multilayer wiring arrangement, and have respective predetermined wiring patterns. The first wiring layer 2 and the second wiring layer 5 are connected by way of via hole 6. The first wiring layer 2 and the second wiring layer 5 are not limited to any particular material, but are preferably made of metal such as copper (Cu).

The insulating layer 3 is interposed between the first wiring layer and the second wiring layer 5. The insulating layer 3 establishes electrical insulation between the first wiring layer 2 and the second wiring layer 5. Materials available to form the insulating layer 3 include, for example, epoxy resins, melamine derivatives such as BT resins, fluorine resins, phenol resins, and polyamide bismaleimides. The insulating layer 3 is not particularly limited in thickness, however in preferred embodiments it typically has a thickness of 25 μm to 60 μm. Note that the lower limit of thickness of the insulating layer 3 must be at least greater than the particle size of the filler 4, to be described next.

The filler 4 is added to the insulating layer 3 to enhance the coefficient of thermal conductivity. The filler 4 is made of a particulate inorganic material having a favorable thermal conductivity. Materials available to form the filler 4 include alumina (Al₂O₃), silica (SiO₂), aluminum nitride (AlN), silicon nitride (SiN), and boron nitride (BN). The filler 4 in the present embodiment has a spherical shape, whereas it should be appreciated that the filler 4 may have an elliptic, amorphous, needle-like, or other shape as long as it is particulate.

The filler 4 in the insulating layer 3 preferably has a volumetric filling rate of 50 vol % to 90 vol %, and even more preferably a volumetric filling rate of 65 vol % to 75 vol %. If the filler 4 falls below a volumetric filling rate of 50 vol %, it fails to provide a sufficient thermal conductivity. On the other hand, if the volumetric filling rate of the filler 4 exceeds 90 vol %, the insulating layer 3 becomes fragile and durability falls. To achieve the volumetric filling rate of the filler 4 of 50 vol % to 90 vol %, it is preferable to mix groups of particles having both relatively large and small sizes. Since the particles of smaller sizes get into gaps between the particles of larger sizes, the filler 4 can be added into the insulating layer 3 more efficiently. By way of example, when a group A having an average particle size of 0.7 μm and a group B having an average particle size of 3 μm (maximum particle size of 15 μm) are mixed to a composition ratio of 1:4, the resulting filler 4 has a volumetric filling rate of 70 vol %.

The filler 4 preferably has a coefficient of thermal expansion that is closer to that of the first wiring layer 2 than that of the insulating layer 3. Namely, a difference between a coefficient of thermal expansion of the filler 4 and a coefficient of thermal expansion of the wiring layer 2 is less than a difference between the coefficient of thermal expansion of the filler 4 and a coefficient of thermal expansion of the insulating layer 3.

By way of further example, assume that the insulating layer 3 is made of epoxy resin (with a coefficient of thermal expansion of 30.3×10⁻⁶/K) and the first wiring layer 2 is made of copper (with a coefficient of thermal expansion of 17.7×10⁻⁶/K). In that instance, the insulating layer 3 can contain alumina (with a coefficient of thermal expansion of 7.8×10⁻⁶/K) as the filler 4 in order to achieve the above-mentioned relationship.

According to the first embodiment, the insulating layer 3 is formed to cover the substrate 1 (and/or the first wiring layer 2), and the filler 4 filled in the insulating layer 3 is exposed on the top surface of the substrate 1 (and/or the first wiring layer 2). The substrate 1 (and/or the first wiring layer 2), thus, has directly contact with a part of the filler 4. Preferably, the contact area between the substrate 1 (and/or the first wiring layer 2) and the filler 4 is greater than that between the substrate 1 (and/or the first wiring layer 2) and the insulating layer 3. This can ensure and enhance the effect, to be described hereinafter.

Since the filler 4 is exposed on the top surface of the substrate 1 (and/or the first wiring layer 2), pits and projections are formed on the substrate 1 (and/or the first wiring layer 2) depending on the distribution of the filler 4. These pits and projections increase the contact area of the substrate 1 (and/or the first wiring layer 2) with the insulating layer 3 and the filler 4, thereby enhancing the anchoring effect (acts as a nail or a wedge). This consequently provides improved adhesion of the substrate 1 (and/or the first wiring layer 2) with the insulating layer 3 and the filler 4.

Even when the circuit board 100 has a rise in temperature, the filler 4 filled in the substrate 1 (and/or the first wiring layer 2) prevents the insulating layer 3 from expanding due to rise in temperature. This consequently makes it possible to avoid the exfoliation arising from the difference of the coefficient of thermal expansion between the substrate 1 (and/or the first wiring layer 2) and the insulating layer 3. By using the filler 4 having the coefficient of thermal expansion closer to that of the first wiring layer 2 than that of the insulating layer 3, even when the circuit board 100 has a rise in temperature, the first wiring layer 2 and the filler 4 cause only a small amount of thermal stress therebetween. The insulating layer 3 and the filler 4 are thus prevented from exfoliating from the first wiring layer 2.

Consequently, it is possible to provide the circuit board 100 with enhanced reliability.

The circuit board 100 of the present embodiment also has improved heat radiation capability at higher temperature. By way of example, alumina used as the filler 4, has a thermal conductivity of around 30 W/mK, which is 100 times greater than that of epoxy resin used as the insulating layer 3. Since the first wiring layer 2 has direct contact with the filler 4 having the favorable thermal conductive property, the heat diffusion using the filler 4 within the insulating layer 3 as a path of heat radiation are increased with the improvement of the heat radiation capability of the circuit board.

The circuit board 100 of the present embodiment may have part of the fillers 4 piled up in vertical direction within the insulating layer 3 with contact with each other. When stress is arisen between the substrate 1 (and/or the first wiring layer 2) and the insulating layer 3 under the high temperature, the stress is spread in vertical direction of the insulating layer 3 among the fillers which are piled up and are in contact with each other. This makes it possible to further enhance the effect on suppressing the exfoliation of the insulating layer 3 and the filler 4 from the substrate 1 (and/or the first wiring layer 2).

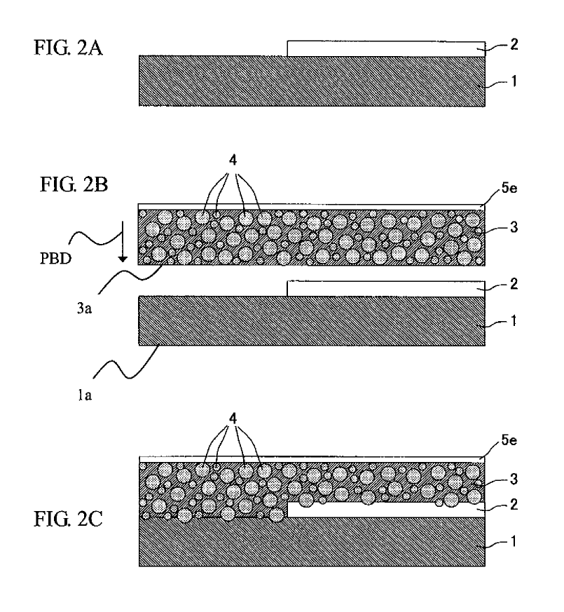

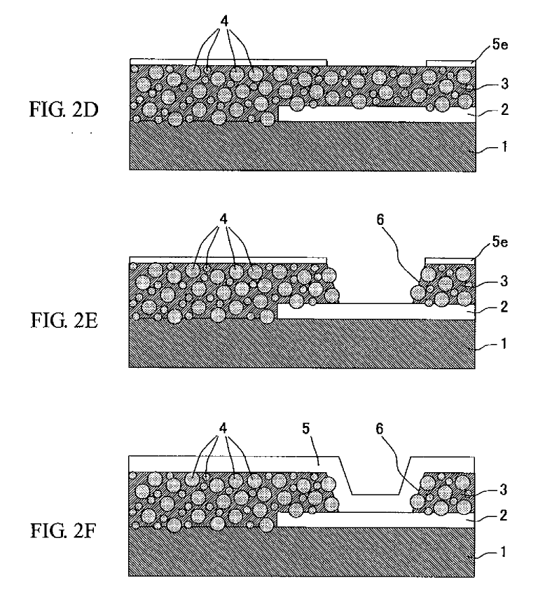

FIGS. 2A to 2F show a method of manufacturing the circuit board 100 in accordance with the present embodiment.

Initially, as shown in FIG. 2A, the first wiring layer 2 is formed on the substrate 1. The first wiring layer 2 can be formed in a predetermined wiring pattern, for example, by a process using photolithography and etching techniques in combination.

As shown in FIGS. 2B and 2C, multilayer sheet of a copper foil 5e coated insulating layer 3 which contains the fillers 4 in a predetermined density is initially provided. Note that the multilayer sheet is formed to be kneaded and mixed by the fillers 4 in the predetermined density and to be covered by the copper foil 5e, where the surface of the fillers 4 is under hydrophilic treatment with silane coupling agent in order to prevent the aggregation of the fillers 4 and to have ease in mixing the fillers 4 in the insulating layer 3 of epoxy resin. The substrate 1 has a first surface 1a. The insulating layer 3 has a second surface 3a. The insulating layer 3 is press-bonded to the substrate 1 in a press-bonding direction PBD so that the first surface 1a is in contact with the second surface 3a. The multilayer sheet attached on the first wiring layer 2 is hardened with pressure bonding under 150° C. for 120 minutes. This pressure bonding treatment makes the filler 4 filled at the bottom surface of the insulating layer 3 exposed, and makes the filler 4 embedded (bit into) the surface boundary between the substrate 1 and the first wiring layer 2.

If part of fillers 4 are piled up in vertical direction and are pressure bonded to be in contact with each other within the insulating layer 3 in this pressure bonding treatment, the pressure of bonding can be propagated effectively to the substrate 1 (and/or the first wiring layer 2) and the fillers 4. Therefore, this can ensure the embedding of the filler 4 in the substrate 1 (and/or the first wiring layer 2).

As shown in FIG. 2D, the copper foil 5e is selectively removed from the position above the area where a via hole 6 which hereinafter be described is to be formed, using photolithography and etching techniques. This makes the forming area for the via hole 6 revealed.

As shown in FIG. 2E, a region from the exposed surface of the insulating layer 3 to the surface of the first wiring layer 2 is removed by irradiating a UV laser (at a wavelength of 355 nm, and pulse width of 15 nsec) from above the copper foil 5e. This makes the via hole 6 with a diameter of approximately 70 μm in the insulating layer 3. The laser used for the UV laser irradiation is preferably adjusted in pulse energy and in energy density so that the resin material of the insulating layer 3 is processed but the filler 4 is hardly affected at all. After the process, as shown in FIG. 2E, the filler 4 added into the insulating layer 3 is partially exposed in the sidewall of the via hole 6.

As shown in FIG. 2F, a thin copper film of approximately 0.5 μm is deposited on the top surface of the copper foil 5e and on the inner surface of the via hole 6 by electroless copper plating using palladium as a catalyst. Subsequently, a copper film of approximately 15 μm is coated on the top surface of the copper foil 5e and on the inner surface of the via hole 6 by electrolytic copper plating using a copper sulfate solution as the plating solution. Consequently, the second wiring layer 5 composed of copper is formed in this manner.

Next, as shown in FIG. 1, the second wiring layer 5 is patterned into a predetermined wiring pattern using a processing method of combination of lithographic and etching techniques. Herewith, the circuit board 100 according to the present invention is manufactured.

### Second Embodiment

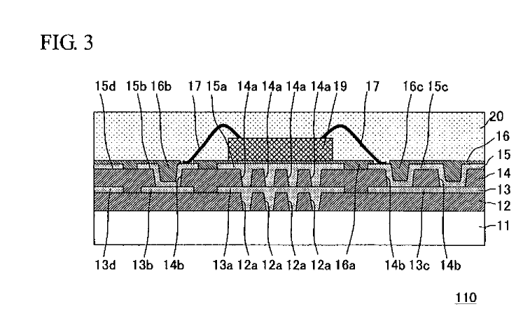

FIG. 3 is a sectional view showing the configuration of a circuit apparatus according to a second embodiment of the present invention.

The circuit apparatus 110 according to the second embodiment, as shown in FIG. 3, uses a substrate 11 with a thickness of from approximately 100 μm to approximately 3 mm (for example approximately 1.5 mm in the present embodiment). For instance, the substrate 11 is constituted of a clad material prepared by stacking a lower metal layer of copper, an intermediate metal layer of an Fe—Ni alloy (the so-called invar alloy) formed on the lower metal layer and an upper metal layer of copper formed on the intermediate metal layer.

A first insulating layer 12, mainly composed of epoxy resin, having a thickness of approximately 60 μm to approximately 160 μm is formed on the surface of the substrate 11. Here, a filler (not shown in Figures) is added to the insulating layer 12 in order to increase thermal conductivity. Note this filler is prepared from the same material composition as the insulating layer 3 (and the filler 4) used in the first embodiment. The filler filled in the insulating layer 12 is exposed at the bottom surface of the insulating layer 12, so the filler is embedded in the surface of the substrate 11 and part of the filler is in direct contact with the substrate 11. Since the filler is exposed to be bit into the surface of the substrate 11, pits and projections are formed on the surface of the substrate 11 depending on the distribution of the fillers. These pits and projections increase the contact area of the substrate 11 with the insulating layer 12, thereby enhancing the anchoring effect. This consequently provide improved adhesion of the substrate 11 to the insulating layer 12.

According to the second embodiment, four via holes 12a, having a diameter of about 100 μm and penetrating through the insulating layer 12, are formed on a region of the insulating layer 12 located under an LSI chip (circuit element) 19 described later at prescribed intervals. A first conductive layer 13 of copper, having a thickness of about 15 μm and including a thermal via potion 13a and wiring portions 13b to 13d is formed on a prescribed region of the insulating layer 12. The thermal via portion 13a of the conductive layer 3 is arranged under the LSI chip 19 and has a portion embedded in the via hole 12a to be in contact with the surface of the substrate 11. This thermal via portion 13a of the conductive layer 13 has a function of transmitting heat to the substrate 11 and radiating the same. The insulating layer 12 exhibits thermal conductivity of about 6 W/(m·K) to about 8 W/(m·K) while the thermal via portion 13a of the conductive layer 13 fills up the via holes 12a. The wiring portions 13b to 13d of the conductive layer 13 are arranged around the LSI chip 19 (and the thermal via portion 13a).

A second insulating layer 14 having a thickness and a composition substantially identical to those of the aforementioned first insulating layer 12 is formed on the conductive layer 13 to cover the conductive layer 13, while a second conductive layer 15 of copper is formed on a prescribed region of the insulating layer 14.

Here, since the insulating layer 14 uses the same material composition as in used in the insulating layer 12, the fillers filled in the insulating layer 14 are exposed at the bottom surface of the insulating layer 14 from above the top surfaces of the insulating layer 12 and the conductive layer 13. This makes the fillers bit into the surfaces of the insulating layer 12 and the conductive layer 13, thereby the conductive layer 13 is in direct contact with a part of the filler. Since the filler is exposed to be embedded into the surfaces of the insulating layer 12 and the conductive layer 13, pits and projections are formed on the top surfaces of the insulating layer 12 and the conductive layer 13 depending on the distribution of the fillers. These pits and projections increase the contact area of the insulating layer 14 with the insulating layer 12 and the conductive layer 13, thereby enhancing the anchoring effect. This consequently provide improved adhesion of the insulating layer 14 to the insulating layer 12 and the conductive layer 13.

More specifically, four via holes 14a, having a diameter of about 100 μm and penetrating through the insulating layer 14 are formed on a region of the insulating layer 14 located under the LSI chip 19. The four via holes 14a are formed on positions corresponding to the four via holes 12a formed in the insulating layer 12 respectively. The insulating layer 14 is also formed with the via holes 14b which have a diameter of about 200 μm and penetrate through the insulating layer 14 in regions corresponding to the wiring portions 13b and 13c of the conductive layer 13 respectively. The conductive layer 15 includes a filling via portion (thermal via portion) 15a, unfilling via portions 15b and 15c and a wiring portion 15d. The thermal via portion 15a of the conductive layer 15 is arranged under the LSI chip 19 and has a portion in contact with the surface of the thermal via portion 13a of the conductive layer 15. This thermal via portion 15a of the conductive layer 15 has a function of transmitting the heat generated from the LSI chip 19 to the thermal via portion 13a of the conductive layer 13 and radiating the same.

Further more, the unfilling via portions 15b of the conductive layer 15 are arranged around the LSI chip 19 and has a portion coating the inner surface of the via hole 14b in U-shape so as to be in contact with the surface of the wiring layer 13c of the conductive layer 13. Plurality of the unfilling via portions 15c are formed as well as the unfilling via portions 15b. The wiring portion 15d of the conductive layer 15 is arranged to be connected to another LSI chip (not shown) or a chip resistor (not shown).

A solder resist layer 16 (solder resist portions 16a, 16b, and 16c) is formed to cover the conductive layer 15 with openings formed in regions corresponding to the unfilling via portion 15b and 15c of the conductive layer 15, and the wiring portion. The solder resist portions 16b and 16c are formed to fill up the unfilling via portions 15b and 15c in the via hole 14b. The solder resist layer 16 is made of thermosetting resin such as melamine derivative, liquid crystal polymer, epoxy resin, PPE (polyphenylene ether) resin, polyimide resin, fluororesin, phenolic resin or polyamide bismaleimide. Liquid crystal polymer, epoxy resin or melamine derivative is preferable as the material for the solder resist layer because of the excellent high frequency characteristics. Further, a filler such as SiO₂ may be added to the solder resist layer 16.

The solder resist layer 16 (the solder resist portions 16a, 16b, and 16c) works as a protection coating for the conductive layer 15. Since the solder resist portions 16b and 16c are formed to fill up the unfilling via portions 15b and 15c in the via holes 14b, the solder resist portions 16b and 16c can work as cushioning materials upon elastic deformation of the unfilling via portions 15b and 15c, thereby inhibiting the unfilling via portions 15b and 15c from excessive deformation. The LSI chip 19 is attached onto a region of the solder resist layer 16 located on the thermal via portion 15a of the conductive layer 15 through an adhesive layer 17 of epoxy resin (not shown) having a thickness of about 20 μm. The thermal expansion coefficient of the LSI chip 19 having a single-crystalline silicon substrate (not shown) is about 4 ppm/° C. This LSI chip 19 is electrically connected to the unfilling via portions 15b and 15c of the conductive layer 15 through wires 17.

As shown in FIG. 3, a sealing resin layer 20 of epoxy resin is formed to cover the LSI chip 19 in order to protect the LSI chip 19 and the like placed in the apparatus.

According to the second embodiment, as hereinabove described, since the solder resist portions 16b and 16c are embedded in the via holes 14b at the unfilling via portions 15b and 15c, adhesion of the unfilling via portions 15b and 15c with the solder resist portions 16b and 16c can be enhanced due to the anchoring effect. The LSI chip 19 is arranged above the via holes 14a while the via holes 14a are filled up with the filling via portion 15a, whereby the heat generated from the LSI chip 19 can be radiated through the filling via portion 15a filling up the via holes 14a. Further, the conductive layer 15 are so formed in U-shape along the inner surfaces of the via holes 14b that the U-shape conductive layer can function as springs against stress from the filling via portion (thermal via portion) 15a. Thus, the stress can be absorbed and released in this manner. This makes it possible to radiate the heat generated from the LSI chip 19 effectively by the filling via portion (thermal via portion) 15a and the thermal via holes 13a, while the stress due to the thermal expansion of the filling via portion (thermal via portion) 15a can be absorbed and released by the unfilling via portions 15b and 15c. Hence, the circuit apparatus with robust adhesion and excellent wiring reliability can be provided.

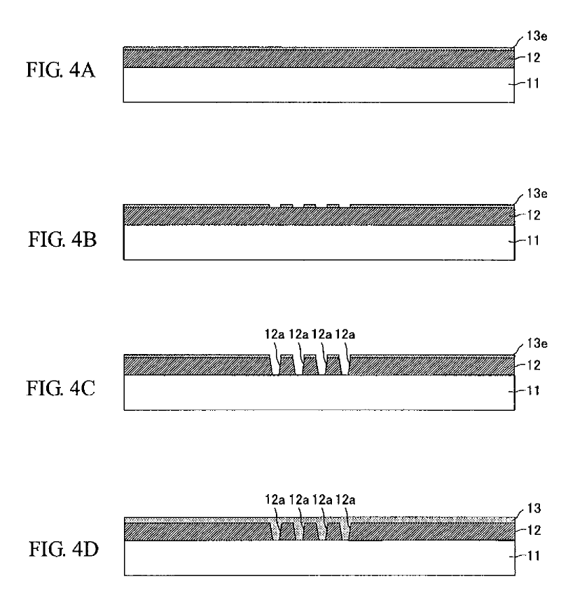

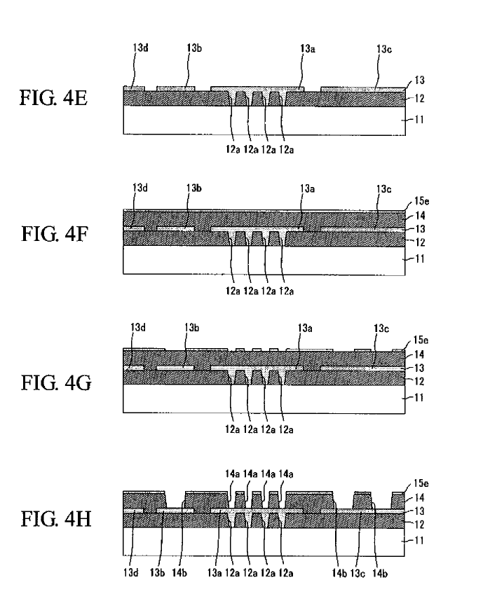

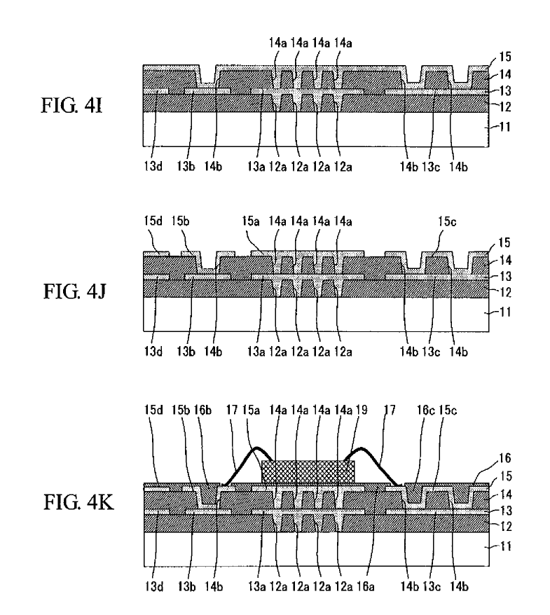

FIGS. 4A to 4K are sectional views for explaining the process for manufacturing the circuit apparatus, shown in FIG. 3, according to the second embodiment of the present invention. With refer to the FIGS. 4A to 4K, the process of manufacturing the circuit apparatus according to the second embodiment will hereinafter be described.

First, as shown in FIG. 4A, the multilayer sheet, including the insulating layer 12 containing fillers at a prescribed filling rate, with copper foil 13e is prepared. The multilayer sheet is attached onto the substrate 11 and is press-bonded at 50° C. for 120 minutes. This press-bonding treatment makes the filler filled at the bottom surface of the insulating layer 12 exposed and embedded (bit) into the surface of the substrate 11.

As shown in FIG. 4B, the region of the copper foil 13e to form the via holes 12a is removed with photolithography technique and etching technique. In this manner, the region for the via holes 12a (refer to FIG. 3) on the insulating layer 12 is exposed.

As shown in FIG. 4C, by applying a carbon dioxide laser beam or a UV laser beam from above the copper foil 13e, a region from the exposed area of the insulating layer 12 to the surface of the substrate 11 is removed. This forms four via holes 12a with a diameter of about 100 μm which penetrate through the insulating layer 12.

As shown in FIG. 4D, the top surfaces of the remaining copper foil 13e and the inner surfaces of the via holes 12a are plated with copper with a thickness of about 0.5 μm by electroless plating. Subsequently, the top surface of the copper foil 13e and the inner surfaces of the via holes 12a are plated by electrolytic plating. According to the second embodiment, an inhibitor and an accelerator are added to a plating solution employed for the electroless plating, so that the inhibitor and the accelerator adsorbed onto the top surfaces of the copper foil 13e and the inner surfaces of the via holes 12a respectively. Thus, the thickness of copper plating films formed on the inner surfaces of the via holes 12a can be increased so that the copper can be embedded in the via holes 12a. Consequently, the conductive layer 13 having the thickness of about 15 μm is formed on the insulating layer 12 while filling up the via holes 12a, as shown in FIG. 4D.

As shown in FIG. 4E, the conductive layer 13 is patterned with photolithography technique and etching technique. This forms the thermal via portions 13a located under the LSI chip 19 (refer to FIG. 3) and the wiring portions 13b to 13d.

As shown in FIG. 4F, the multilayer sheet, including the insulating layer 14 containing fillers at a prescribed filling rate, with copper foil 15e is prepared. The multilayer sheet is attached onto the conductive layer 13 and the insulating layer 12 to cover the same and is press-bonded at 150° C. for 120 minutes. This press-bonding treatment makes the filler filled at the bottom surface of the insulating layer 14 exposed and embedded (bit) into the surfaces of the conductive layer 13 and the insulating layer 12.

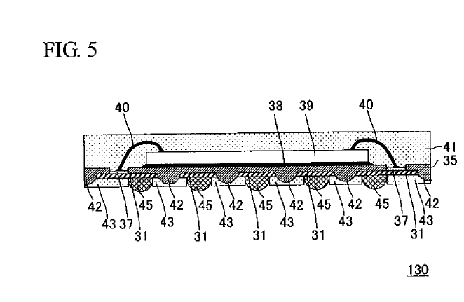

As shown in FIG. 4G, the region of the copper foil 15e to form the via holes 14a and 14b (refer to FIG. 5) is removed with photolithography technique and etching technique. In this manner, the region for the via holes 14a and 14b on the insulating layer 14 is exposed.

As shown in FIG. 4H, by applying a carbon dioxide laser beam or a UV laser beam from above the copper foil 15e, a region from the exposed area of the insulating layer 14 to the surface of the conductive layer 13 is removed. This forms four via holes 14a with a diameter of about 100 μm which penetrate through the insulating layer 14. Further in this process, the via holes 14b with a diameter of about 200 μm which penetrate through the insulating layer 14 are formed, simultaneously.

As shown in FIG. 4I, the top surfaces of the remaining copper foil 15e and the inner surfaces of the via holes 14a and 14b are plated with copper with a thickness of about 0.5 μm by electroless plating. Subsequently, the top surface of the copper foil 15e and the inner surfaces of the via holes 14a and 14b are plated by electrolytic plating. At this moment, an inhibitor and an accelerator are added to a plating solution employed for the electroless plating, so that the inhibitor and the accelerator adsorbed onto the top surfaces of the copper foil 15e and the inner surfaces of the via holes 14a respectively. Thus, the thickness of copper plating films formed on the inner surfaces of the via holes 14a can be increased so that the copper can be embedded in the via holes 14a. Consequently, the conductive layer 15 having the thickness of about 15 μm is formed on the insulating layer 14 while filling up the via holes 14a. The conductive layer 15 is formed only on the inner surfaces of the via holes 14b without filling up because the via diameter of the via hole 14b is greater than the thickness of the conductive layer 15.

As shown in FIG. 4J, the conductive layer 15 is patterned with photolithography technique and etching technique. This forms the filling via portions (thermal via portions) 15a located under the LSI chip 19 (refer to FIG. 5), unwilling via portions 15b and 15c, and the wiring portions 15d, which are located around the LSI chip 19.

Note that more than three unfilling via portions 15b and 15c (via holes 14b) are provided surrounding the LSI chip 19. The LSI chip 19 is arranged in a region with a boundary formed by lines between the more than three unwilling via portions 14b. The circuit apparatus according to the second embodiment is designed so that all of the via holes except for via holes located under circuit elements such as the LSI chip 19 are not filled up to be unfilling via holes like the via hole 14b.

As shown in FIG. 4K, the solder resist layer 16 having the openings in the regions corresponding to the wire bonding area of the unfilling via portions 15b and 15c is formed to cover the conductive layer 15. At this time, the solder resist portions 16b and 16c fills up the concave upper surfaces of the unfixing via portions 15b and 15c. Note that the conductive layer 15 composed of copper (Cu) has the Young's modulus of about 129.8 GPa, and the solder resist layer 16 has the Young's modulus of about 10 GPa, therefore, the Young's modulus of the solder resist layer 16 is lower than that of the conductive layer 15.

Then, the LSI chip 19 is attached onto the portion of the solder resist portion 16a located on the thermal via portions 15a of the conductive layer 15 through the adhesive layer (not shown) of epoxy resin having the thickness of about 50 μm. The thickness of the adhesive layer becomes about 20 μm after this attachment of the LSI chip 19. Thereafter the LSI chip 19 and the wire bonding areas of the unfilling via portions 15b and 15c of the conductive layer 15 are electrically connected with each other through the wires 17.

Finally, as shown in FIG. 3, the sealing resin layer 20 of epoxy resin is formed to cover the LSI chip 19 in order to protect the LSI chip 19 provided on the substrate 11, thereby forming the circuit apparatus 110 according to the second embodiment.

### Third Embodiment

FIG. 5 is a sectional view showing a circuit apparatus according to a third embodiment of the present invention. The circuit apparatus 130 according to the third embodiment includes a wiring layer 31, a insulating layer 35, a circuit element 39, a sealing resin layer 40, a solder resist layer 43, and an external electrode 45.

The wiring layer 31 has a prescribed pattern composed of conductive materials. The wiring layer 31 may be composed of a single metal such as copper (Cu), however may be formed with multiple metal layers. For instance, the connection credibility in wire bonding can be improved by forming silver coating (Ag) on a metal layer of copper.

A filler (not shown) is added to the insulating layer 35 so as to enhance the thermal conductivity of the insulating layer 35. Note that the insulating layer 35 uses the same material composition as in used in the insulating layer 3 (and the filler 4) according to the first embodiment. The fillers filled in the insulating layer 35 are exposed at the bottom surface of the insulating layer 35 from above the top surfaces of the wiring layer 31. This makes the filler bit into the surfaces of the wiring layer 31, thereby the wiring layer 31 is in contact with a part of the filler. Since the filler is exposed to be embedded into the surfaces of the wiring layer 31, pits and projections are formed on the top surfaces of the wiring layer 31 depending on the distribution of the fillers. These pits and projections increase the contact area of the wiring layer 31 with the insulating layer 35, thereby enhancing the anchoring effect. This consequently provide improved adhesion of the wiring layer 31 to the insulating layer 35.

The insulating layer 35 has a protrusion 42 protruding from inbetween of the wiring layer 31 to the bottom surface side. This protrusion 42 prevents from arising the migration between the wiring layer 31. Further, the filler contained in the insulating layer 35 is exposed at the protrusion 42. The surface of the protrusion 42 has pits and protrusions formed depending on the distribution of the fillers. These pits and protrusions increases the surface area, so heat radiation performance is enhanced at the protrusion 42. Thus, the reliability of the circuit apparatus 130 can be improve when the temperature of the circuit element 39 rises, as compared with a circuit apparatus without the pits and protrusions on the surface of protrusion 42.

The circuit element 39 may, for instance, be semiconductor chips such as IC (integrated circuit), LSI (large-scale integration) and the like. The circuit element 39 is attached onto a prescribed region on the insulating layer 35 through an adhesive layer 38 of epoxy resin. Note that not only insulating epoxy resin, but also conductive solder can be used for adhering as the adhesive layer 38.

The sealing resin layer 40 seals the circuit element 39 disposed above the wiring layer 31 in order to protect the circuit element 39 from affection of the outer world. The materials used for the sealing resin layer 40 may, for instance, be thermosetting and insulating resin such as epoxy resin. Destruction and deterioration of the circuit element 39 at operation test before implementing the circuit apparatus 130 can be avoided by sealing the circuit element 39 with the sealing resin layer 40.

The solder resist layer 43 has openings corresponding to the regions of the external electrode 45 and is formed to cover the bottom surface side (opposite from the circuit element 39) of the wiring layer 31 including the protrusion 42 in order to protect the wiring layer 31 from the affection of the outer world. Here, the solder resist layer 43 is made of thermosetting resins such as melamine derivative, liquid crystal polymer, epoxy resin, PPE (polyphenylene ether) resin, polyimide resin, fluororesin, phenolic resin or polyamide bismaleimide. Liquid crystal polymer, epoxy resin or melamine derivative is preferable as the material for the solder resist layer 43 because of the excellent high frequency characteristics. Further, a filter such as SiO₂ may be added to the solder resist layer 43.

The array of external electrodes 45 are disposed corresponding to the openings of the solder resist layer 43 in order to connect with the wiring layer 31 as connecting terminals.

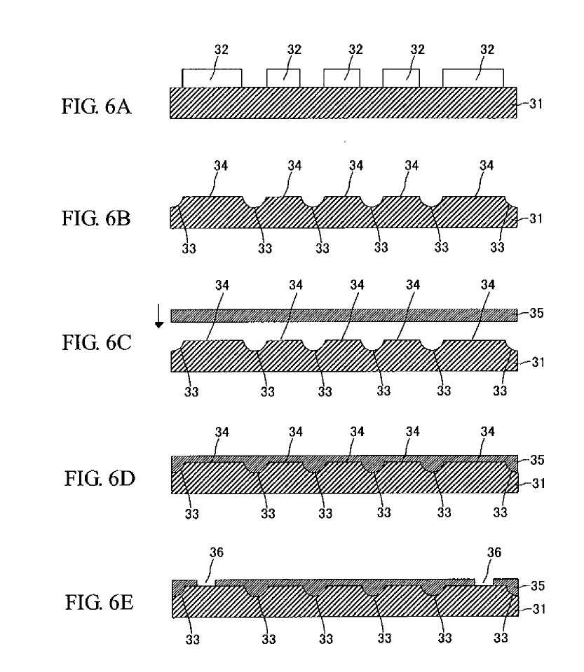

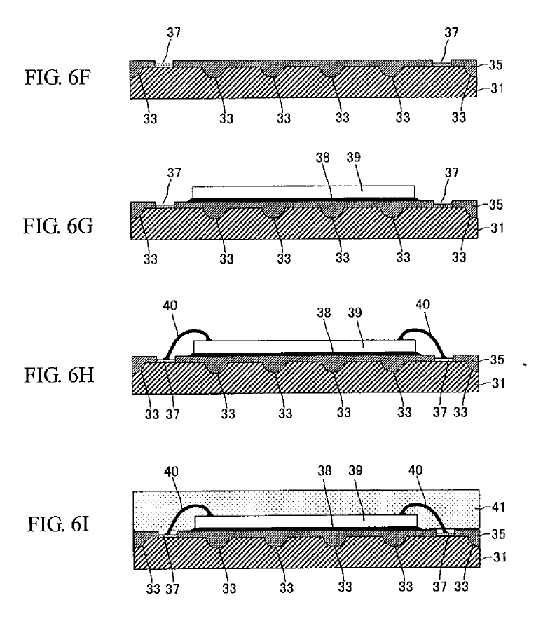

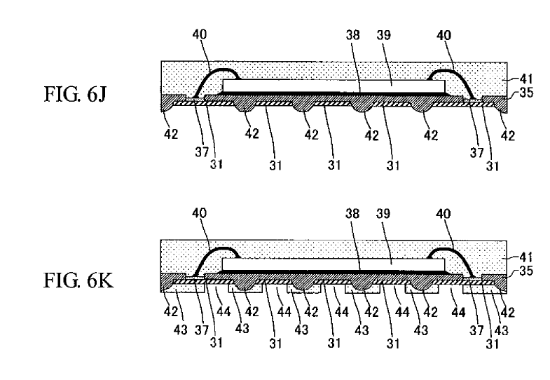

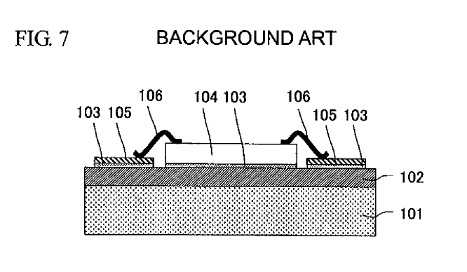

FIGS. 6A to 6K are sectional views for explaining the process for manufacturing the circuit apparatus according to the third embodiment of the present invention.

First, as shown in FIG. 6A, a resist 32 is selectively-formed on a copper board (becomes wiring layer 31 in later process) in accordance with a pattern of the wiring layer with lithography method. The copper board 31 has, for instance, a thickness of 125 μm. More specifically, the resist coating with a thickness of 20 μm is applied onto the copper board 31 with laminator device. A photo mask having the pattern of the wiring layer is used for UV exposure. The resist 32 is selectively formed on the copper board 31 by developing with Na₂CO₃ solution and removing unexposed region of the resist. Note that preparations such as polishing and cleaning the surface of the copper board 31 before laminate coating is preferred so as to improve the adhesion of the resist 32 to the copper board 31.

As shown in FIG. 6B, exposed portions of the copper board 31 are half-etched with ferric chloride solution to form a trench 33 in a region not for the wiring pattern 34, and the resist 32 is exfoliated with exfoliating solution such as NaOH solution. The depth of the trench 33 is, for example, 50 μm.

As shown in FIG. 6C and FIG. 6D, an insulating layer sheet of insulating layer 35 containing fillers (not shown) at a prescribed rate is prepared. Note that the insulating layer sheet is formed to be kneaded and mixed by the fillers in the predetermined density, where the surface of the filler is under hydrophilic treatment with silane coupling agent in order to prevent the aggregation of the fillers and to have ease in mixing the fillers in the insulating layer 35 of epoxy resin. The insulating layer sheet attached on the copper board 31 is hardened with pressure bonding under 150° C. for 120 minutes. This pressure bonding treatment makes the filler filled at the bottom surface of the insulating layer 35 exposed, and makes the filler embedded (bit) into the surfaces of the wiring pattern 34 and the trench 33 of the copper board 31.

As shown in FIG. 6E, the insulating layer 35 is patterned with a UV laser to expose openings 36 of the copper board 31 for wire bonding in later process.

As shown in FIG. 6F, the exposed surfaces of the copper board 31 are plated with silver with a thickness of about 10 μm by electrolytic plating or electroless plating. Thus, a plate film 37 of Ag is formed on the surface of the copper board 31.

As shown in FIG. 6G, the circuit element 39 is attached onto the insulating layer 35 through an adhesive layer 38 of epoxy resin (not shown) having a thickness of about 50 μm. The thickness of the adhesive layer 38 becomes about 20 μm after this attachment of the circuit element 39. Thus, the circuit element 39 is fixed on the insulating layer 35. Note that the materials available for the adhesive layer 38 for fixating the circuit element 39 may be not only the insulating materials mentioned above, but also conductive solder materials. In this case, after printing solder in the region for loading the circuit element 39, the circuit element 39 is fixed with reflow process, while the circuit element 39 is loaded on a predetermined location.

As shown in FIG. 6H, an electrode terminal (not shown) of the circuit element 39 and the solder coating 37 (a predetermined area of the wiring layer 31) are electrically connected with each other by wire bonding. Use of a metal wire as a wire 40 for the wire bonding makes it possible to improve the connection reliability with the solder coating 37 of Ag.

As shown in FIG. 6I, the sealing resin layer 41 of epoxy resin is formed to seal the circuit element 39 with transfer-mold method.

As shown in FIG. 6J, a protrusion 42 is formed by half-etching the bottom surface of the copper board 31 with ferric chloride solution to have the copper board 31 thinned with a thickness of 20 μm, and by exposing part of the insulating layer 35 which is embedded in the trench 33 (refer to FIG. 6I). The height of the protrusion 42 is, for instance, 30 μm. Note that pits and protrusions are formed on the surface of the protrusion 42 in response to the state that the filler is embedded in the inner surface of the trench 33.

As shown in FIG. 6K, the solder resist layer 43 is laminated to cover the bottom side (opposite to the circuit element 39) of the wiring layer 31 including the protrusion 42. Here, the thickness of the solder resist layer 43 is, for example, 40 μm. The laminating condition may be a temperature of 110° C., a time of 1 minutes to 2 minutes, and 2 barometric pressure. Afterwards, a part of the solder resist layer 43 is hardened with after baking process. Subsequently, an opening 44 is formed at a region corresponding to the external electrode 45 by exposing and patterning the solder resist layer 43 with glass mask.

Finally, as shown in FIG. 5, a solder ball (external electrode) 45 is formed as an external connecting terminal at the bottom surface of the wiring layer 31 (exposed portion at the opening 44 of the solder resist layer 43) with solder printing method. More specifically, the solder ball 45 is formed by printing a solder paste process-pasted with resin and solder ingredient at a prescribed area with screen mask and by heating at the temperature of melting point of the solder. Or in another method, flux may be initially applied on the bottom surface of the wiring layer 31 and the solder ball 45 may be mounted on the wiring layer 31.

The circuit apparatus 130 according to the third embodiment can be obtained by the processes described above.

It should be understood that the embodiments disclosed herein are in all respects illustrative, not restrictive. The scope of the present invention shall be given not by the description of the foregoing embodiments but by the scope of the accompanying claims, and all modifications made within the meanings and scope of equivalency of the claims shall be included therein.

What is claimed as new and is desired to be secured by Letters Patent of the United States is:

1. A circuit board comprising:
a substrate having a first surface;
an insulating layer having a second surface and connected to said substrate, the first surface being in contact with the second surface; and
heat-conductive particles provided in said insulating layer, a part of said particles projecting from the second surface of said insulating layer and being in contact with the first surface of said substrate.

2. The circuit board according to claim 1, wherein a contact area between said substrate and said particles is greater than a contact area between said substrate and said insulating layer.

3. The circuit board according to claim 1, wherein said particles are in contact with each other in a thickness direction of the insulating layer.

4. The circuit board according to claim 1, wherein said substrate includes a wiring layer provided on the first surface, and wherein the particles projecting from the second surface are in contact with said wiring layer.

5. The circuit board according to claim 4, wherein a difference between a coefficient of thermal expansion of said particles and a coefficient of thermal expansion of said wiring layer is less than a difference between the coefficient of thermal expansion of said particles and a coefficient of thermal expansion of said insulating layer.

6. The circuit board according to claim 1, wherein said insulating layer has a thickness of at least 25 μm and at most 60 μm.

7. The circuit board according to claim 1, wherein said particles comprise at least one of alumina (Al₂O₃), silica (SiO₂), aluminum nitride (AlN), silicon nitride (SiN), and boron nitride (BN).

8. The circuit board according to claim 1, wherein said particles are spherical, elliptic, amorphous, or needle-shaped.

9. The circuit board according to claim 1, wherein a volumetric filling rate of said particles in the insulating layer is at least 50 vol % and at most 90 vol %.

10. The circuit board according to claim 1, wherein a volumetric filling rate of said particles in the insulating layer is at least 65 vol % and at most 75 vol %.

11. The circuit board according to claim 1, wherein said particles comprises a first particle group having a first average particle diameter and a second particle group having a second average particle diameter larger than the first average particle diameter.

12. The circuit board according to claim 11, wherein an amount of the first particle group is less than an amount of the second particle group.

13. The circuit board according to claim 1, wherein said particles comprises hydrophilic surfaces.

14. The circuit board according to claim 1, further comprising:
a thermal via portion provided in the insulating layer to conduct heat.

15. A circuit apparatus comprising:
a substrate having a first surface;
an insulating layer having a second surface and connected to said substrate, the first surface being in contact with the second surface;
heat-conductive particles provided in said insulating layer, a part of said particles projecting from the second surface of said insulating layer and being in contact with the first surface of said substrate; and
a circuit element provided on the insulating layer.

16. A method of manufacturing a circuit board comprising:
providing a substrate; and
press-bonding an insulating layer including heat-conductive particles to said substrate in a press-bonding direction.

17. The method of manufacturing the circuit board according to claim 16, wherein an insulating layer is press-bonded to said substrate so that the heat-conductive particles contacts with each other in the press-bonding direction.

18. The method of manufacturing the circuit board according to claim 16, wherein the heat-conductive particles are obtained by mixing a first particle group having a first average particle diameter and a second particle group having a second average particle diameter larger than the first average particle diameter.

19. The circuit board according to claim 18, wherein an amount of the first particle group is less than an amount of the second particle group.
